(19) United States
(12) Patent Application Publication
(10) Pub. No.: US 2026/0011978 A1
(43) Pub. Date: Jan. 8, 2026

(54) LIGHT EMITTING DEVICE

(71) Applicant: CANON KABUSHIKI KAISHA, Tokyo (JP)

(72) Inventors: TATSURO UCHIDA, Tokyo (JP); TAKAKO SUGA, Kanagawa (JP); TAKESHI UCHIDA, Kanagawa (JP)

(21) Appl. No.: 19/249,364

(22) Filed: Jun. 25, 2025

(30) Foreign Application Priority Data
Jul. 3, 2024 (JP) 2024-107551

(51) Int. Cl. H01S 5/042; G01S 7/481; G01S 17/931

(52) U.S. Cl. CPC H01S 5/042; G01S 7/4815; G01S 17/931

(57) ABSTRACT

A light emitting device includes a substrate, a first light emitting element arranged on the substrate, a second light emitting element arranged on the substrate, and a wiring layer arranged over the first light emitting element and the second light emitting element. Each of the first light emitting element and the second light emitting element is a vertical cavity surface emitting laser (VCSEL) element. The first light emitting element is configured to emit light by being supplied with electric power from the wiring layer. The second light emitting element is configured such that electric power for causing the second light emitting element to emit light is not supplied from the wiring layer to the second light emitting element.

### BACKGROUND

### Technical Field

The present disclosure relates to a light emitting device.

### Description of the Related Art

Japanese Patent Laid-Open No. 2000-114656 discloses a surface emitting laser array device in which a plurality of surface emitting laser elements are arranged. In the surface emitting laser array device disclosed in Japanese Patent Laid-Open No. 2000-114656, dummy elements are arranged at both ends of a row of surface emitting laser elements. As a result, it is disclosed in Japanese Patent Laid-Open No. 2000-114656 that the uniformity of characteristics of the plurality of surface emitting laser elements can be improved.

In light emitting devices such as those described in Japanese Patent Laid-Open No. 2000-114656, further improvement in uniformity of characteristics is required.

### SUMMARY

Accordingly, the present disclosure is directed to a light emitting device capable of further improving uniformity of characteristics.

According to one aspect of the present specification, there is provided a light emitting device including a substrate, a first light emitting element arranged on the substrate, a second light emitting element arranged on the substrate, and a wiring layer arranged over the first light emitting element and the second light emitting element. Each of the first light emitting element and the second light emitting element is a vertical cavity surface emitting laser (VCSEL) elements. The first light emitting element is configured to emit light by being supplied with electric power from the wiring layer. The second light emitting element is configured such that electric power for causing the second light emitting element to emit light is not supplied from the wiring layer to the second light emitting element.

Further features of the present disclosure will become apparent from the following description of exemplary embodiments with reference to the attached drawings.

### BRIEF DESCRIPTION OF THE DRAWINGS

FIG. 1 is a plan view of a light emitting device according to a first embodiment.

FIG. 2 is an enlarged plan view of the light emitting device according to the first embodiment.

FIGS. 3A and 3B are cross-sectional views of the light emitting device according to the first embodiment.

FIG. 4A is an enlarged cross-sectional view of the light emitting device according to the first embodiment.

FIG. 4B is an enlarged cross-sectional view of a light emitting device according to a modification of the first embodiment.

FIG. 5 is a plan view of a light emitting device according to a second embodiment.

FIG. 6 is a plan view of a light emitting device according to a third embodiment.

FIG. 7 is a plan view of a light emitting device according to a fourth embodiment.

FIG. 8 is a plan view of a light emitting device according to a fifth embodiment.

FIG. 9 is a plan view of a light emitting device according to a sixth embodiment.

FIG. 10 is a plan view of a light emitting module according to a seventh embodiment.

FIG. 11 is a cross-sectional view of the light emitting module according to the seventh embodiment.

FIG. 12 is a plan view of a light emitting module according to an eighth embodiment.

FIG. 13 is a cross-sectional view of a light emitting module according to a ninth embodiment.

FIG. 14 is an enlarged cross-sectional view of the light emitting device according to the ninth embodiment.

FIG. 15 is a block diagram illustrating a schematic configuration of a ranging device according to a tenth embodiment.

FIGS. 16A and 16B are block diagrams illustrating a configuration example of a mobile object according to an eleventh embodiment.

### DESCRIPTION OF THE EMBODIMENTS

Hereinafter, embodiments of the present disclosure will be described with reference to the drawings. The same or corresponding elements are denoted by the same reference numerals throughout the several drawings, and the description thereof may be omitted or simplified.

### First Embodiment

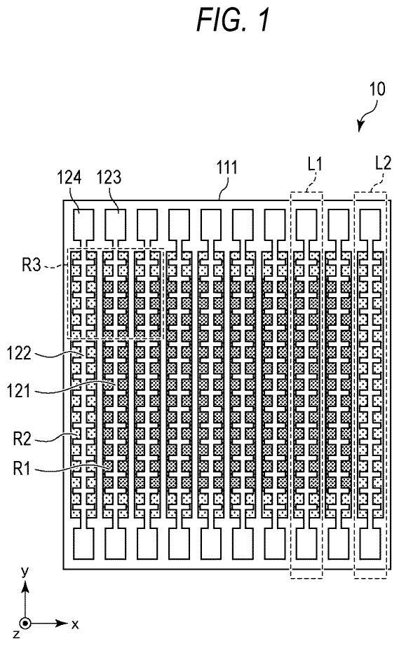

FIG. 1 is a plan view of a light emitting device 10 according to the present embodiment. The light emitting device 10 is a surface emitting semiconductor light emitting device in which a plurality of light emitting elements are arranged on a substrate 111. The substrate 111 may be a compound semiconductor substrate such as GaAs. Each of the plurality of light emitting elements is constituted by a vertical cavity surface emitting laser (VCSEL) element having a distributed Bragg reflector (DBR). However, the light emitting element may be an element other than the VCSEL, such as a light emitting diode.

As shown in the coordinate axes of FIG. 1, a horizontal direction of FIG. 1 is defined as an x direction, a vertical direction of FIG. 1 is defined as a y direction, and a direction perpendicular from the paper surface of FIG. 1 is defined as a z direction. FIG. 1 shows a planar structure of the light emitting device 10 in the xy plane. A plurality of light emitting units are arranged in an array in the xy plane, and the emission direction of laser light from the light emitting elements is the z direction.

The light emitting device 10 includes a plurality of first light emitting elements L1 and two second light emitting elements L2 arranged on the substrate 111. Each of the first light emitting elements L1 and the second light emitting elements L2 has an elongated shape. Each of the long sides of the first light emitting elements L1 and the second light emitting elements L2 extends in the y direction. The plurality of first light emitting elements L1 are arranged in the x direction. The two second light emitting elements L2 are arranged so as to sandwich the plurality of first light emitting elements L1 at both ends in the x direction. That is, each of the two second light emitting elements L2 is arranged between the plurality of first light emitting elements L1 and the end of the substrate 111. In the example of FIG. 1, eight first light emitting elements L1 and two second light emitting elements L2 are shown, but the numbers of the first light emitting elements L1 and the second light emitting elements L2 are not limited thereto, and can be appropriately changed.

A wiring layer is arranged over a region where the first light emitting elements L1 and the second light emitting elements L2 are arranged. The wiring layer includes a wiring 121 (first wiring) arranged over each of the plurality of first light emitting elements L1 and a wiring 122 (second wiring) arranged over each of the plurality of second light emitting elements L2. Each of the wirings 121 and 122 is arranged so as to extend in the y direction. The plurality of wirings 121 are not electrically connected to each other. In addition, the plurality of wirings 121 and the wirings 122 are not electrically connected to each other.

The wiring 121 is connected to a pad 123. The wiring 122 is connected to a pad 124. The pad 123 and the pad 124 are electrodes for wire bonding. The pad 123 and the pad 124 are connected to pads of a mounting board on which the light emitting device 10 is mounted by wires. Electric power for driving the first light emitting element L1 may be supplied to the pad 123 from a control circuit arranged on the mounting board through a wire. The plurality of pads 123 respectively corresponding to the wirings 121 of the plurality of first light emitting elements L1 are electrically isolated from each other, and electric power for driving can be supplied to the wirings 121 at different timings. Therefore, the plurality of first light emitting elements L1 may emit light at different timings.

In the example of FIG. 1, the pads 123 and the pads 124 are arranged at both ends of the substrate 111 in the y direction, and are arranged so as to be aligned in the x direction of FIG. 1, but the arrangement of the pads 123 and the pads 124 is not limited thereto. For example, the pads 123 and the pads 124 may be provided only at one end of the substrate 111. The metal material constituting the wirings 121 and 122 and the pads 123 and 124 may be, for example, laminated film in which a lower layer is Au (gold)/Ti (titanium) and upper layer is a Cu plating layer formed on a Cu (copper)/Ti seed layer. The Cu plating layer is formed by an electroplating process.

Each of the first light emitting elements L1 and the second light emitting elements L2 includes a plurality of mesas processed to have a trapezoidal cross section. Each of the plurality of mesas is a VCSEL element that emits laser light in the z direction from the upper surface of the mesa. The light emitting device 10 is provided with an effective mesa region R1 and a dummy mesa region R2. The mesas in the effective mesa region R1 are configured to emit light by being supplied with electric power from the wiring layer. The mesas in the dummy mesa region R2 are configured such that electric power for causing the light emitting element to emit light is not supplied from the wiring layer. The vicinity of both ends of the first light emitting element L1 in the y direction is in the dummy mesa region R2, and the central portion of the first light emitting element L1 is in the effective mesa region R1. The whole of the second light emitting element L2 is in the dummy mesa region R2. Therefore, the dummy mesa region R2 is arranged so as to surround the effective mesa region R1.

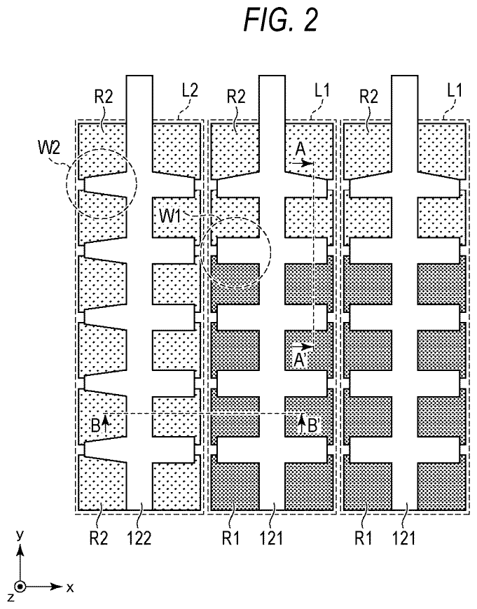

FIG. 2 is an enlarged plan view of the light emitting device 10 according to the present embodiment. FIG. 2 is an enlarged view of a region R3 in FIG. 1. As shown in FIG. 2, the wiring 121 has a shape in which a long wiring extending in the vertical direction and a large number of short wirings intersecting the long wiring in a cross shape are combined. The wiring 121 is arranged so as to overlap three sides of each of the plurality of mesas having a rectangular shape in plan view. Thus, the wiring 121 can uniformly supply a current to each mesa while opening the upper surface of each mesa. One wiring 121 is connected to two rows of mesas. Thus, these two rows of mesas emit light at the same timing. Note that the wiring 122 is also designed in the same pattern as the wiring 121.

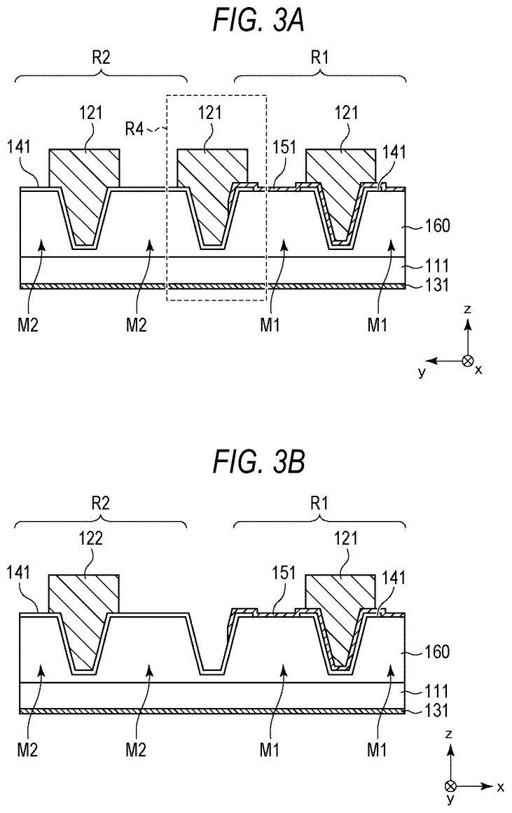

FIGS. 3A and 3B are cross-sectional views of the light emitting device 10 according to the present embodiment. FIG. 3A shows a cross section taken along line A-A′ of FIG. 2, and FIG. 3B shows a cross section taken along line B-B′ of FIG. 2.

FIG. 3A shows a cross-sectional structure of the mesas and the wiring layer in the vicinity of the boundary between the effective mesa region R1 and the dummy mesa region R2 in the first light emitting element L1. As shown in FIG. 3A, a semiconductor layer 160 formed by epitaxial growth is arranged on the front surface side of the substrate 111. In the semiconductor layer 160, a plurality of trapezoidal grooves are formed at predetermined intervals, and the semiconductor layer 160 between the grooves has a mesa structure.

On the groove of the effective mesa region R1, the wiring 121 is formed so as to fill the groove with the transparent conductive film 151 and the insulating film 141 interposed therebetween. In the vicinity of the effective mesa region R1, the transparent conductive film 151 is formed so as to electrically connect the wiring 121 and the upper surface of the semiconductor layer 160. The upper surface of the mesa in the effective mesa region is covered with a transparent conductive film 151. In addition, on the side surface and the bottom surface of the groove in the vicinity of the effective mesa region R1, an insulating film 141 is arranged so as to prevent a short circuit between the transparent conductive film 151 and the inner layer of the semiconductor layer 160. The transparent conductive film 151 is a conductive material that transmits emitted laser light, and may be, for example, indium tin oxide (ITO). The insulating film 141 is an insulating material that insulates the semiconductor layer 160 from the wiring 121 or the transparent conductive film 151, and may be, for example, silicon oxide. In this way, a plurality of effective mesas M1 are formed in the effective mesa region R1.

A back surface common electrode 131 is formed on a surface (back surface) of the substrate 111 opposite to the semiconductor layer 160 side. When a predetermined potential difference is applied between the wiring 121 and the transparent conductive film 151 on the front surface side and the back surface common electrode 131 on the back surface side, laser light is emitted from the upper surface of the effective mesa M1. The transparent conductive film 151 is arranged on the upper surface of the effective mesa M1, and the laser beam passes through the transparent conductive film 151 and is emitted to the outside. The wiring 121 is opened on the upper surface of the effective mesa M1 so as not to block the laser beam.

In the vicinity of the dummy mesa region R2, the insulating film 141 (second insulating film) is formed so as to cover the upper surface of the semiconductor layer 160, the side surface of the groove, and the bottom surface of the groove. On the groove of the dummy mesa region R2, the wiring 121 is formed so as to fill the groove with the insulating film 141 interposed therebetween. Thus, a plurality of dummy mesas M2 are formed in the dummy mesa region R2. The wiring 121 and the dummy mesa M2 are insulated from each other by the insulating film 141. Since the wiring 121 is not electrically connected to the dummy mesa M2, unlike the effective mesa M1, the laser beam is not emitted from the dummy mesa M2.

In the boundary between the effective mesa region R1 and the dummy mesa region R2 (region R4 in FIG. 3A), only the insulating film 141 is formed in a portion between the wiring 121 and the dummy mesa M2. In the region R4, the insulating film 141 and the transparent conductive film 151 are formed in a portion between the wiring 121 and the effective mesa M1. Thus, the wiring 121 in the region R4 supplies electric power to the right adjacent effective mesa M1 in the region R4, and does not supply electric power to the left adjacent dummy mesa M2 in the region R4.

FIG. 3B shows a cross-sectional structure of the mesas and the wiring layer near the boundary between the effective mesa region R1 of the first light emitting element L1 and the dummy mesa region R2 of the second light emitting element L2. In the effective mesa region R1 of the first light emitting element L1, similarly to FIG. 3A, the wiring 121, the transparent conductive film 151, and the insulating film 141 are arranged, and the effective mesa M1 is formed.

As shown in FIG. 3B, a wiring 122 is formed on the groove of the dummy mesa region R2 of the second light emitting element L2 so as to fill the groove with the insulating film 141 interposed therebetween. In addition, in the vicinity of the dummy mesa region R2 of the second light emitting element L2, the insulating film 141 (first insulating film) is formed so as to cover the upper surface of the semiconductor layer 160, the side surface of the groove, and the bottom surface of the groove. Thus, the wiring 122 and the dummy mesa M2 are insulated from each other. Since the boundary between the effective mesa region R1 and the dummy mesa region R2 is also the boundary between the first light emitting element L1 and the second light emitting element L2, the wirings 121 and 122 are not arranged in the groove of the boundary between the effective mesa region R1 and the dummy mesa region R2. Description of other structures is omitted because it is similar to that of FIG. 3A.

Effects obtained by arranging the dummy mesa M2 as in the present embodiment will be described. The wiring layer is patterned by a photolithography technique. In the formation of the photoresist for patterning the wiring layer, even when exposure is performed using a photomask having a pattern in which the same shape is repeated, a resist having different shapes may be formed depending on the position in the array of the light emitting elements.

For example, it is necessary to reduce the wiring resistance in order to inject a current having a high current value into the VCSEL element or to equalize the light outputs of the VCSEL elements that emit light at the same time. Therefore, a thick wiring layer may be formed by electroplating using a plating resist. In such a case, for example, a thick plating resist of 10 μm or more may be employed. In the step of forming such a thick resist, the shape of the resist may have position dependency due to a difference in the degree of thermal shrinkage during baking. FIG. 2 schematically shows the position dependency of the shape of the resist. In the example of FIG. 2, a rectangular wiring is formed in accordance with the pattern of the photomask at the wiring end W1 on the inner side of the array of light emitting elements, but a wiring having a narrow tip is formed at the wiring end W2 on the outermost periphery of the array of light emitting elements. As described above, a pattern shape distribution may occur in which the wiring near the outermost periphery of the array of light emitting elements is narrower than the wiring inside the array of light emitting elements.

When the distribution of the shape of the wiring layer occurs in the array constituted by the plurality of light emitting units, the uniformity of the characteristics between the light emitting units may decrease due to a difference in injection characteristics of carriers, a difference in vignetting of emitted light, or the like. Therefore, in the present embodiment, the dummy mesas M2 are arranged in the dummy mesa region R2 around the effective mesa region R1. Since the dummy mesa M2 does not emit laser light unlike the effective mesa M1, it is not affected by the pattern shape distribution of the wiring. Therefore, by setting the dummy mesa region R2 to a portion where the influence of the pattern shape distribution of the wiring is large, such as in the vicinity of the outer periphery of the array of the light emitting elements, it is possible to reduce the influence on the characteristics of the pattern shape distribution of the wiring, and thus it is possible to make the characteristic distribution in the array closer to uniform. Therefore, according to the present embodiment, the light emitting device 10 capable of further improving the uniformity of characteristics is provided.

In the present embodiment, the dummy mesa M2 is formed by disposing the insulating film 141 between the wirings 121 and 122 and the semiconductor layer 160 to insulate the wirings 121 and 122 from the semiconductor layer 160. The structure of the semiconductor layer 160 constituting the dummy mesa M2 and the structure of the semiconductor layer 160 constituting the effective mesa M1 are the same. That is, the difference between the element structure of the dummy mesa M2 and the element structure of the effective mesa M1 is only the difference in the pattern of the insulating film 141 and the pattern of the transparent conductive film 151.

As a method of reducing the influence of the pattern shape distribution of the wiring, it is conceivable to reduce the pattern shape distribution of the wiring of the wiring layer by correcting the shape of the vicinity of the outer periphery of the array of the light emitting elements in advance in the pattern design of the photomask of the wiring layer. However, since the degree of pattern correction of the photomask varies depending on various factors such as the element pitch and the mesa height, many trials and errors are required to optimize the correction pattern. Therefore, the method of arranging the dummy mesa M2 of the present embodiment is effective in that it does not require many trials and errors as compared with the method of performing the pattern correction of the photomask.

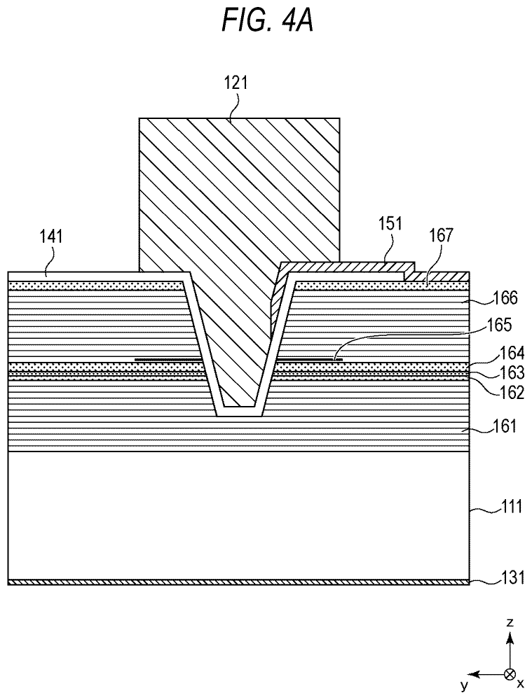

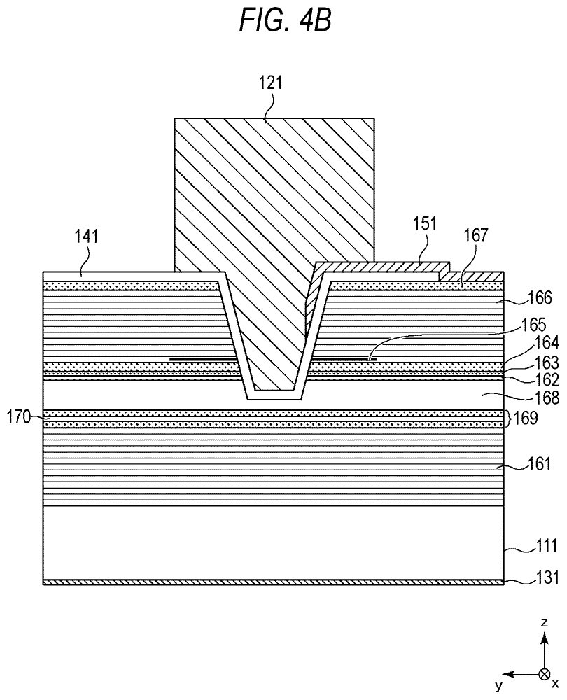

Hereinafter, a more specific configuration example of the semiconductor layer 160 and an example of a manufacturing process of the light emitting device 10 will be described. FIG. 4A is an enlarged cross-sectional view of the light emitting device 10 according to the present embodiment. FIG. 4A is an enlarged view of the region R4 in FIG. 3A.

A bottom DBR 161 is arranged on the substrate 111. A spacer layer 162 is arranged on the bottom DBR 161, an active layer 163 is arranged on the spacer layer 162, and a spacer layer 164 is arranged on the active layer 163. A top DBR 166 is arranged on the spacer layer 164. The oxide confinement portion 165 is formed by selectively oxidizing a part of the top DBR 166. A contact layer 167 is arranged on the top DBR 166. The lower DBR 161, the spacer layer 162, the active layer 163, the spacer layer 164, the oxide confinement portion 165, the top DBR 166, and the contact layer 167 correspond to the semiconductor layer 160 in FIG. 3A.

The spacer layer 162, the active layer 163, and the spacer layer 164 are resonator portions of the light emitting device 10. The bottom DBR 161 and the top DBR 166 are reflectors that confine light generated in the active layer 163 in the resonator. An oxide confinement portion 165 is formed in a part of the top DBR 166 so as to limit the path of the current injected into the active layer 163.

Next, a manufacturing process of the light emitting device 10 will be described. The light emitting device 10 is assumed to be a VCSEL array element that emits light in the 940 nm band.

First, for example, an n-type GaAs substrate is prepared as the substrate 111. Next, the semiconductor layer 160 constituting the bottom DBR 161, the spacer layer 162, the active layer 163, the spacer layer 164, the top DBR 166 including the selective oxidation layer, and the contact layer 167 is epitaxially grown on the substrate 111. These semiconductor layers may be formed by metal organic chemical vapor deposition or molecular beam epitaxy.

The bottom DBR 161 may be configured by, for example, repeatedly stacking an n-type GaAs layer and an n-type AlGaAs layer by a predetermined number of layers. The spacer layers 162 and 164 may be, for example, GaAs layers or AlGaAs layers. The active layer 163 may be, for example, a multiple quantum well structure including a plurality of InGaAs well layers each sandwiched by AlGaAs barrier layers. The selective oxidation layer which is a part of the top DBR 166 may be formed of, for example, a p-type Al_{0.98}GaAs layer. The top DBR 166 other than the selective oxidation layer may be formed by, for example, repeatedly stacking a p-type GaAs layer and a p-type AlGaAs layer by a predetermined number of layers. The contact layer 167 may be a p-type GaAs layer.

Next, a silicon oxide (SiOₓ) film (not shown) is formed on the contact layer 167 by plasma CVD. Then, the silicon oxide film is patterned using a photolithography technique and a wet etching technique.

Next, etching for forming a mesa structure using the silicon oxide film as a hard mask is performed using a dry etching technique. In this etching, it is desirable to cut the contact layer 167, the top DBR 166, the oxide confinement portion 165, the spacer layer 164, the active layer 163, and the spacer layer 162. Further, it is more desirable to cut a part of the bottom DBR 161. Then, heat treatment is performed in a water vapor atmosphere to selectively oxidize the p-type Al_{0.98}GaAs layer from the side wall portion of the mesa, thereby forming the oxide confinement portion 165.

Next, a resist in which a portion of the silicon oxide film on the mesa where the hard mask remains is opened is formed by a photolithography technique. Then, the silicon oxide film in the opening of the resist is selectively wet-etched using buffered hydrofluoric acid, and then the resist is removed.

Next, an insulating film is formed so as to cover the mesa structure. Then, openings are formed in the insulating film by a photolithography technique and an etching technique. Thus, the patterned insulating film 141 is formed. Next, an indium tin oxide film is formed as a transparent conductive film so as to cover the mesa structure, and heat treatment is performed as necessary. Next, patterning of the transparent conductive film is performed using a photolithography technique and a wet etching technique so that the transparent conductive film remains on the effective mesa M1. Thus, the patterned transparent conductive film 151 is formed.

Next, a wiring layer is formed. The wiring layer includes a lower wiring layer and an upper wiring layer. The lower wiring layer is formed using a lift-off technique. First, a photoresist is formed by a photolithography technique in a region where the lower wiring layer is not to be formed. Next, a metal layer such as Au/Ti is formed so as to cover the entire surface by vacuum evaporation. Thereafter, an unnecessary metal layer on the photoresist is removed together with the photoresist to form a lower wiring layer.

The upper wiring layer is formed by an electroplating technique. First, a seed layer of Cu/Ti or the like is formed. Then, a plating resist is formed by a photolithography technique in a region where the upper wiring layer is not to be formed. When the plating resist is formed, baking may be performed. Next, a thick plating layer such as Cu is formed on the seed layer corresponding to the opening of the photoresist by electroplating. Next, the plating resist is removed. Then, unnecessary portions of the seed layer are removed.

Next, an insulating film (not shown in FIG. 4A) such as silicon oxide is formed so as to cover the entire surface. Thereafter, the insulating film covering the pads 123 and 124 of the wiring layer is selectively removed by a photolithography technique and a wet etching technique to expose the pads 123 and 124.

Next, the substrate 111 is thinned by polishing from the surface opposite to the surface on which the semiconductor layer 160 is formed, and then the back surface common electrode 131 is formed on the polished surface of the substrate 111.

As described above, the VCSEL array element including the effective mesa M1 and the dummy mesa M2 as shown in FIGS. 1 to 4A is manufactured. However, the structure and the manufacturing method of the light emitting device 10 are not limited thereto, and the light emitting device 10 may be, for example, a planar VCSEL array element.

Further, in a VCSEL element and a VCSEL array described below, a higher current injection value is required, and by adopting the configuration of the present disclosure, a light source capable of generating an optical pulse having a short pulse width and a high peak output power can be realized. FIG. 4B is an enlarged cross-sectional view of a light emitting device 10 according to a modification of the present embodiment. FIG. 4B is an enlarged view of the region R4 in FIG. 3A. The n-type bottom DBR 161 is arranged on the n-type substrate 111. A non-doped spacer layer 169 is arranged on the bottom DBR 161, and a saturable absorption layer 170 is provided in the non-doped spacer layer 169. An n-type spacer layer 168 is arranged on the non-doped spacer layer 169. Non-doped layers are laminated on the n-type spacer layer 168 in the order of the spacer layer 162, the active layer 163, and the spacer layer 164. The p-type top DBR 166 including the selective oxidation layer is arranged on the spacer layer 164. The contact layer 167 is arranged on the top DBR 166. The bottom DBR 161, the non-doped spacer layer 169 including the saturable absorption layer 170, the n-type spacer layer 168, the spacer layer 162, the active layer 163, the spacer layer 164, the top DBR 166 including the selective oxide layer, and the contact layer 167 correspond to the semiconductor layer 160 of FIG. 3A.

Although the VCSEL element having the prismatic mesa structure has been described in the drawings of the present embodiment, the mesa structure is not limited thereto, and the VCSEL element of the present embodiment may have a columnar mesa structure, for example. In addition, although the groove forming the mesa structure has been described as a trapezoidal shape in the drawings of the present embodiment, but the shape of the groove is not limited thereto, and the VCSEL element of the present embodiment may have a rectangular groove, for example. The same applies to the following embodiments.

### Second Embodiment

In the present embodiment, a modification in which the arrangement of the light emitting elements and the planar layout of the wiring layer are changed from those in the first embodiment will be described. In the present embodiment, description of elements common to those of the first embodiment may be omitted or simplified.

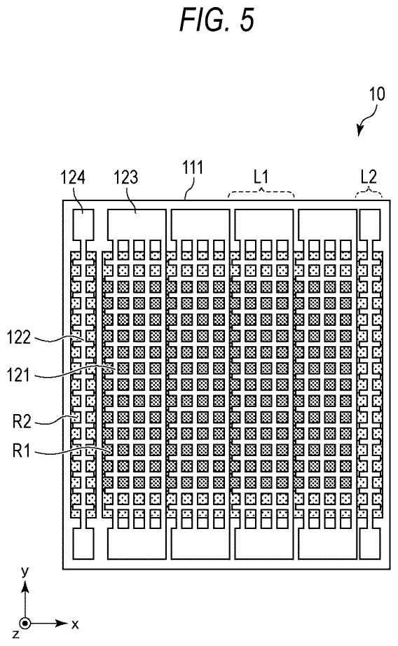

FIG. 5 is a plan view of the light emitting device 10 according to the present embodiment. The light emitting device 10 of the present embodiment includes four first light emitting elements L1 arranged in the x direction and two second light emitting elements L2 arranged so as to sandwich the four first light emitting elements L1.

Each of the first light emitting elements L1 and the second light emitting elements L2 includes a plurality of mesas as in the first embodiment. The light emitting device 10 is provided with an effective mesa region R1 and a dummy mesa region R2. The vicinity of both ends of the first light emitting elements L1 in the y direction is a dummy mesa region R2, and the central portion of the first light emitting elements L1 is the effective mesa region R1. In the present embodiment, a range of two rows x four columns in the vicinity of both ends in the y direction of the first light emitting element L1 is the dummy mesa region R2. The range of thirteen rows x four columns of the central portion of the first light emitting element L1 is the effective mesa region R1. The effective mesas of thirteen rows x four columns emit light at the same timing. The entire second light emitting element L2 (seventeen rows×two columns) is the dummy mesa region R2. Also in the present embodiment, the dummy mesa region R2 is arranged so as to surround the effective mesa region R1.

A plurality of pads 123 are arranged so as to respectively correspond to the wirings 121 of the plurality of first light emitting elements L1. The plurality of pads 123 are electrically separated from each other, and electric power for driving can be supplied to the wirings 121 at different timings. Therefore, the plurality of first light emitting elements L1 may emit light at different timings.

Among the mesas of seventeen rows×four columns included in the first light emitting element L1, in the first column (left end), the wiring 121 is arranged in a U-shape so as to overlap three sides excluding one left side of the mesa. In addition, among the mesas of seventeen rows x four columns included in the first light emitting element L1, in the second column, the third column, and the fourth column (right end), the wiring 121 is arranged in a lattice shape so as to overlap the four sides of the mesas. Since the wirings 121 of the two adjacent first light emitting elements L1 need to be electrically separated from each other, it is required to secure a space for insulation between the wirings 121. Since the wiring 121 does not overlap the side of the mesa at one end of the first light emitting element L1, the insulating space can be efficiently secured. By assigning the secured area to the wiring width, the wiring resistance can be further reduced.

Since the transparent conductive film 151 is arranged on the upper surface of the mesa in the effective mesa region R1, the diffusion of carriers is the same between the case where the wiring 121 overlaps three sides of the mesa and the case where the wiring 121 overlaps four sides of the mesa. Therefore, an element in which the wiring 121 overlaps three sides of the mesa and an element in which the wiring 121 overlaps four sides of the mesa have the same light emission characteristics.

In the example of FIG. 5, the pads 123 and the pads 124 are arranged at both ends of the substrate 111 in the y direction and are arranged so as to be aligned in the x direction of FIG. 5, but the arrangement of the pads 123 and the pads 124 is not limited thereto. For example, the pads 123 and the pads 124 may be provided only at one end of the substrate 111. However, when the pads 123 are arranged at both ends of the substrate 111, carriers can be injected into the wiring 121 from both upper and lower sides, so that the light emission characteristics can be made more uniform. The pad 124 is connected to the wiring 122 for the dummy mesa, but is not connected to the wiring 121 for the effective mesa. Therefore, even when the pad 124 is not provided, the dummy mesa may not emit light, and thus the pad 124 may be omitted.

As described above, the light emitting device 10 of the present embodiment is a modification in which four first light emitting elements L1 each including the effective mesa of thirteen rows×four columns are arranged. Also in the present embodiment, the light emitting device 10 capable of further improving the uniformity of characteristics is provided as in the first embodiment.

### Third Embodiment

In the present embodiment, a modification in which the arrangement of the light emitting elements and the planar layout of the wiring layer are changed from those in the second embodiment will be described. In the present embodiment, description of elements common to those of the second embodiment may be omitted or simplified.

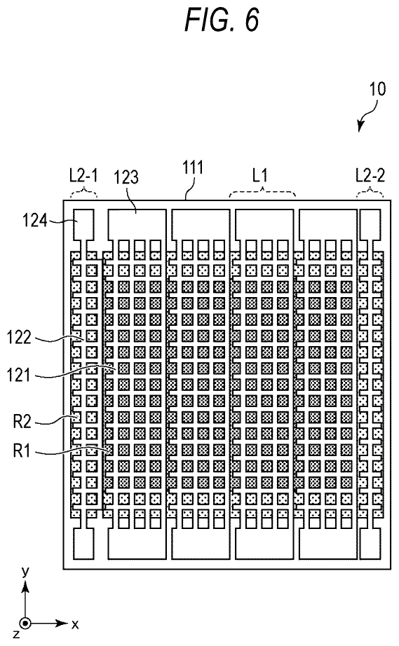

FIG. 6 is a plan view of the light emitting device 10 according to the present embodiment. In the light emitting device 10 of FIG. 6, a second light emitting element L2-1 and a second light emitting element L2-2 are arranged so as to sandwich the four first light emitting elements L1. The configuration of the second light emitting element L2-1 and the configuration of the second light emitting element L2-2 are different from each other.

The configuration of the second light emitting element L2-2 is the same as that of the second light emitting element L2 in the second embodiment.

On the other hand, in the wiring 122 over the second light emitting element L2-1, unlike the wiring 122 over the second light emitting element L2-2, the first column (left side) is arranged in a U-shape and the second column (right side) is arranged in a lattice shape, similarly to the wiring 122 over the adjacent first light emitting element L1. Therefore, the pattern of the wiring 122 over the second light emitting element L2-1 and the pattern of the wiring 122 over the second light emitting element L2-2 are different from each other.

The second light emitting element L2-1 and the second light emitting element L2-2 do not emit light. Therefore, even when the pattern of the wiring 122 over the second light emitting element L2-1 and the pattern of the wiring 122 over the second light emitting element L2-2 are different from each other as in the present embodiment, the same light emission characteristics as in the case of the second embodiment can be obtained. Therefore, also in the present embodiment, the light emitting device 10 capable of further improving the uniformity of the characteristics as in the first embodiment is provided.

### Fourth Embodiment

In the present embodiment, a modification in which the arrangement of the light emitting elements and the planar layout of the wiring layer are changed from those in the second embodiment will be described. In the present embodiment, description of elements common to those of the second embodiment may be omitted or simplified.

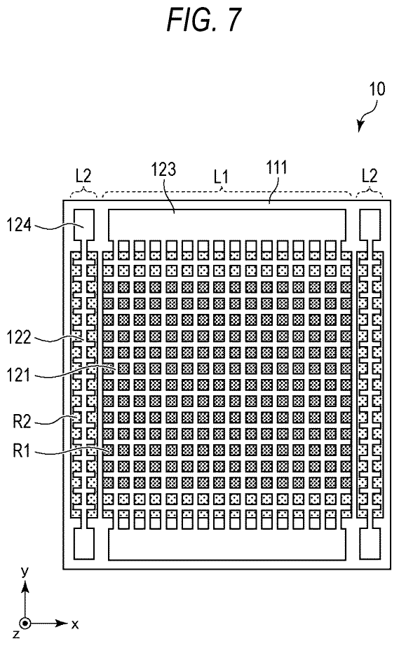

FIG. 7 is a plan view of the light emitting device 10 according to the present embodiment. The light emitting device 10 of the present embodiment includes one first light emitting element L1 and two second light emitting elements L2 arranged so as to sandwich the one first light emitting element L1. In the present embodiment, the entire effective mesa region R1 is included in one first light emitting element L1.

In the present embodiment, a range of two rows×sixteen columns in the vicinity of both ends in the y direction of the first light emitting element L1 is the dummy mesa region R2. A range of thirteen rows×sixteen columns of the central portion of the first light emitting element L1 is the effective mesa region R1. The thirteen rows×16 columns effective mesas emit light at the same timing. The entire second light emitting element L2 (seventeen rows×two columns) is the dummy mesa region R2. Also in the present embodiment, the dummy mesa region R2 is arranged so as to surround the effective mesa region R1.

In the present embodiment, the pad 123 is connected to the entire wiring 121 of one first light emitting element L1. Therefore, all of the plurality of effective mesas in the light emitting device 10 emit light at the same timing.

As in the above-described embodiments, the transparent conductive film 151 is arranged in the effective mesa region R1. One transparent conductive film 151 may be continuously arranged on a plurality of effective mesas, or a plurality of separated transparent conductive films 151 may be arranged.

In the example of FIG. 7, the pads 123 and the pads 124 are arranged at both ends of the substrate 111 in the y direction, but the arrangement of the pads 123 and the pads 124 is not limited thereto. For example, the pad 123 and the pads 124 may be provided only at one end of the substrate 111. However, when the pads 123 are arranged at both ends of the substrate 111, carriers can be injected into the effective mesas from both upper and lower sides through the wiring 121, and thus the light emission characteristics can be made more uniform.

As described above, the light emitting device 10 of the present embodiment is a modification in which one first light emitting element L1 including thirteen rows x sixteen columns of effective mesas is arranged. Also in the present embodiment, the light emitting device 10 capable of further improving the uniformity of characteristics is provided as in the first embodiment.

### Fifth Embodiment

In the present embodiment, a modification in which the planar layout of the wiring layer is changed from that of the fourth embodiment will be described. In the present embodiment, description of elements common to the fourth embodiment may be omitted or simplified.

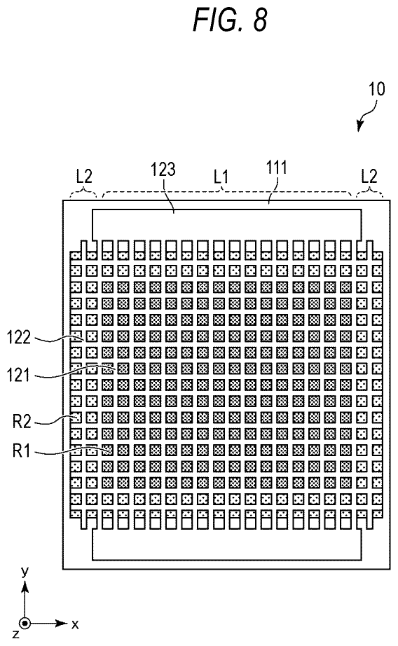

FIG. 8 is a plan view of the light emitting device 10 according to the present embodiment. The present embodiment is different from the fourth embodiment in that the pad 124 is not provided and the wiring 121 is connected to the wiring 122. In other words, the wiring having the same potential as the wiring 121 is arranged not only over the effective mesa region R1 but also over the dummy mesa region R2. As in the above-described embodiments, an insulating film 141 is arranged between the wiring 122 and the semiconductor layer of the dummy mesa. Therefore, even in the configuration of the present embodiment, electric power is not supplied from the wiring 122 to the dummy mesa, and the second light emitting element L2 does not emit light. Therefore, the light emitting device 10 of the present embodiment can perform the same operation as the light emitting device 10 of the fourth embodiment.

As described above, the light emitting device 10 of the present embodiment is a modification in which the pad 124 is omitted and the wiring 121 is connected to the wiring 122. Also in the present embodiment, the light emitting device 10 capable of further improving the uniformity of characteristics is provided as in the first embodiment.

### Sixth Embodiment

In the present embodiment, a modification in which the planar layout of the wiring layer is changed from that of the fifth embodiment will be described. In the present embodiment, description of elements common to the fifth embodiment may be omitted or simplified.

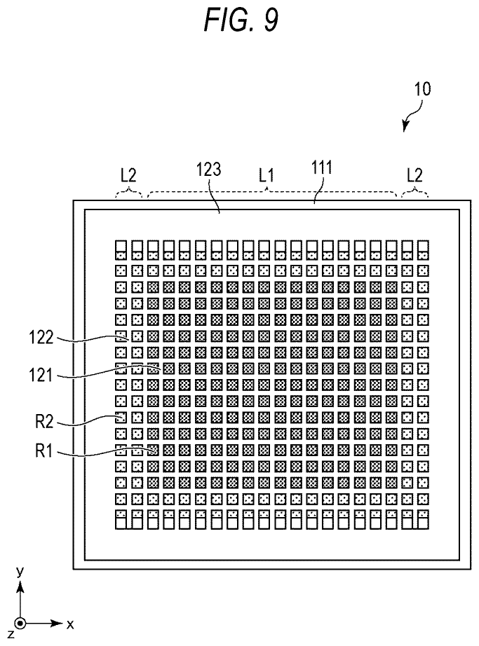

FIG. 9 is a plan view of the light emitting device 10 according to the present embodiment. In the present embodiment, the pad 123 is arranged so as to surround the first light emitting element L1 and the second light emitting elements L2, and is connected to the outer peripheral ends of the wiring 121 and the wiring 122.

An insulating film 141 is arranged between the wiring 122 and the semiconductor layer of the dummy mesa. Therefore, even in the configuration of the present embodiment, electric power is not supplied from the wiring 122 to the dummy mesa, and the second light emitting element L2 does not emit light. Therefore, the light emitting device 10 of the present embodiment can perform the same operation as the light emitting device 10 of the fourth embodiment.

In addition, in the present embodiment, the pad 123 is arranged so as to surround the first light emitting element L1 and the second light emitting elements L2. As a result, carriers can be injected into the effective mesas from the four sides through the wiring 121, so that the light emission characteristics can be made more uniform.

As described above, the light emitting device 10 of the present embodiment is a modification in which the pad 123 is arranged so as to surround the first light emitting element L1 and the second light emitting elements L2. Also in the present embodiment, the light emitting device 10 capable of further improving the uniformity of characteristics is provided as in the first embodiment.

### Seventh Embodiment

In the present embodiment, a configuration example of a light emitting module including the light emitting device 10 of the second embodiment will be described. In the present embodiment, description of elements common to those of the second embodiment may be omitted or simplified.

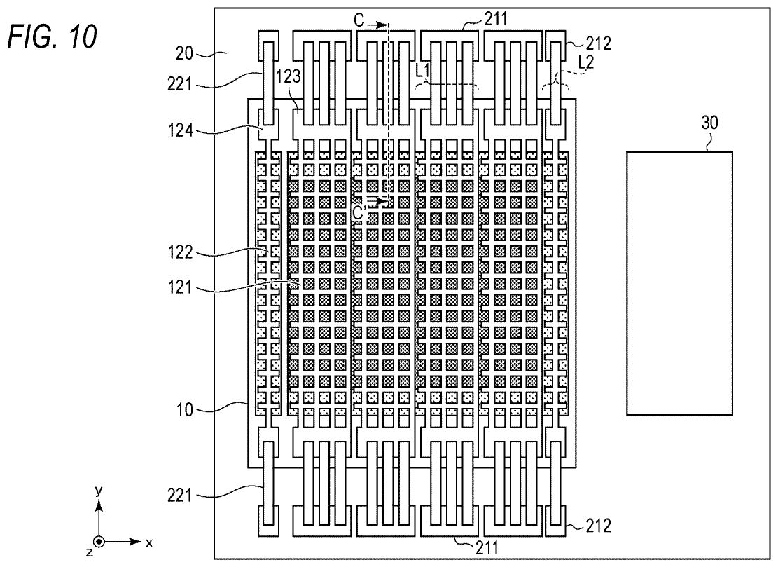

FIG. 10 is a plan view of the light emitting module according to the present embodiment. The light emitting module includes the light emitting device 10 of the second embodiment, a mounting board 20, and a control circuit 30. The mounting board 20 is a board such as a printed circuit board compatible with wire bonding and surface mounting. The chip constituting the light emitting device 10 is mounted on the mounting board 20 so that the surface on which the back surface common electrode 131 is arranged faces the mounting board 20. A chip constituting the control circuit 30 is also mounted on the mounting board 20. The mounting board 20 has a plurality of pads 211 and 212. Each of the plurality of pads 211 is connected to the control circuit 30, and each of the plurality of pads 212 is connected to a ground terminal of the mounting board 20.

The pads 123 of each of the four first light emitting elements L1 are connected to the corresponding pads 211 of the mounting board 20 via three wires 221. The control circuit 30 supplies electric power for driving to the first light emitting element L1 via the pad 211 and the wire 221. The control circuit 30 is configured to independently control the light emission of the four first light emitting elements L1. A process of connecting the pads with the wires 221 is performed using a wire bonder.

Since the number of wires 221 connected between one pad 123 and one pad 211 is plural, resistance and inductance of the wires 221 can be reduced as compared with the case where the number of wires 221 is one. Accordingly, the light emitting performance of the light emitting device 10 can be improved. However, this is not essential, and the number of wires 221 connected between one pad 123 and one pad 211 may be one.

Each of the pads 124 of the two second light emitting elements L2 is connected to the corresponding pad 212 of the mounting board 20 via one wire 221. Accordingly, the ground potential is supplied from the mounting board 20 to the pad 124 of the second light emitting element L2.

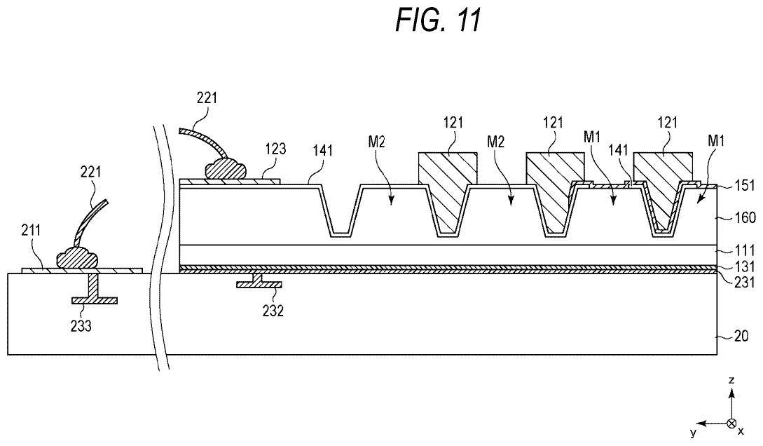

FIG. 11 is a cross-sectional view of the light emitting module according to the present embodiment. FIG. 11 shows a cross section taken along line C-C′ in FIG. 10.

As shown in FIG. 11, pads 211 and 231 are arranged on the mounting surface of the mounting board 20. Internal wirings 232 and 233 are arranged in inner layers of the mounting board 20. The pad 211 is a surface terminal for wire bonding. The pad 211 is electrically connected to the control circuit 30 via the internal wiring 233. Therefore, the electric power for driving output from the control circuit 30 is supplied to the effective mesa M1 via the internal wiring 233, the pad 211, the wire 221, the pad 123, the wiring 121, and the transparent conductive film 151. Since the insulating film 141 is arranged between the wiring 121 and the dummy mesa M2 and the wiring 121 and the dummy mesa M2 are insulated from each other, electric power for driving is not supplied to the dummy mesa M2.

The pad 231 is a surface terminal for surface mounting. The pad 231 is electrically connected to the ground terminal of the mounting board 20 via the internal wiring 232. The back surface common electrode 131 of the light emitting device 10 is connected to the pad 231 by a member such as solder or conductive paste. Therefore, the back surface common electrode 131 is electrically connected to the ground terminal of the mounting board 20 via the pad 231 and the internal wiring 232.

As described above, according to the present embodiment, a light emitting module including the light emitting device 10 of the second embodiment is provided. A light emitting module including the light emitting device 10 of the embodiments other than the second embodiment can be similarly realized.

Since the ground potential is supplied to the pad 124 of the second light emitting element L2 and the ground potential is also supplied to the back surface common electrode 131, the potential difference applied to the dummy mesa M2 of the second light emitting element L2 is zero. Therefore, in the dummy mesa M2 of the second light emitting element L2, the insulating film 141 may or may not be arranged.

### Eighth Embodiment

In the present embodiment, a modified example in which the configuration of the second light emitting element L2 is changed with respect to the light emitting module of the seventh embodiment will be described. In the present embodiment, description of elements common to the seventh embodiment may be omitted or simplified.

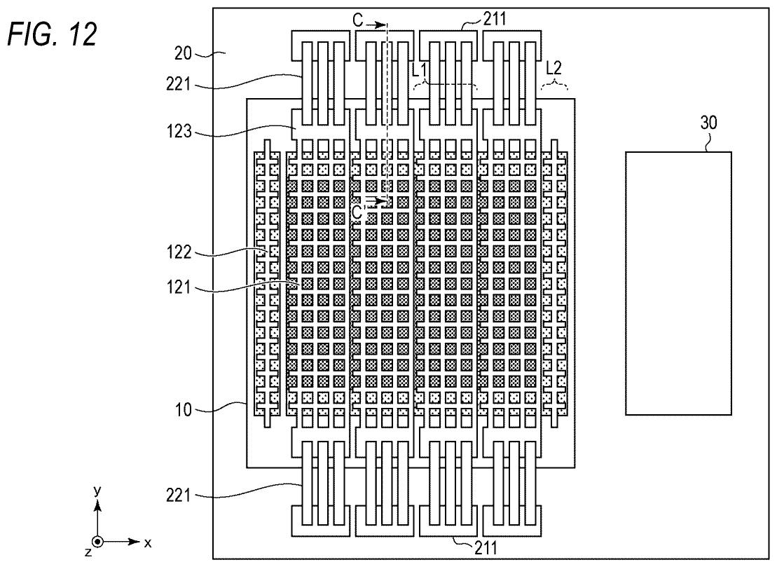

FIG. 12 is a plan view of the light emitting module according to the present embodiment. The present embodiment is different from the seventh embodiment in that the pad 124 for the second light emitting element L2 is not arranged on the light emitting device 10, and the pad 212 is not arranged on the mounting board 20. In this case, the wiring 122 of the second light emitting element L2 is in a floating state. The dummy mesa M2 of the second light emitting element L2 does not emit light because there is no potential difference that causes light emission. Therefore, also in the present embodiment, a light emitting module capable of performing the same operation as that of the seventh embodiment is provided.

As described above, it is not necessary to supply the ground potential to the second light emitting element L2. Although FIG. 12 shows an example in which the pad 124 is not arranged, the present embodiment is not limited thereto. For example, the wire 221 may not be connected to the pad 124 even though the pad 124 is arranged, and in this case, the wiring 122 of the second light emitting element L2 is also in a floating state.

### Ninth Embodiment

In the present embodiment, a modification in which the structure of the light emitting element is changed from the mesa type to the planar type in the light emitting module of the seventh embodiment or the eighth embodiment will be described. In the present embodiment, description of elements common to the seventh embodiment or the eighth embodiment may be omitted or simplified.

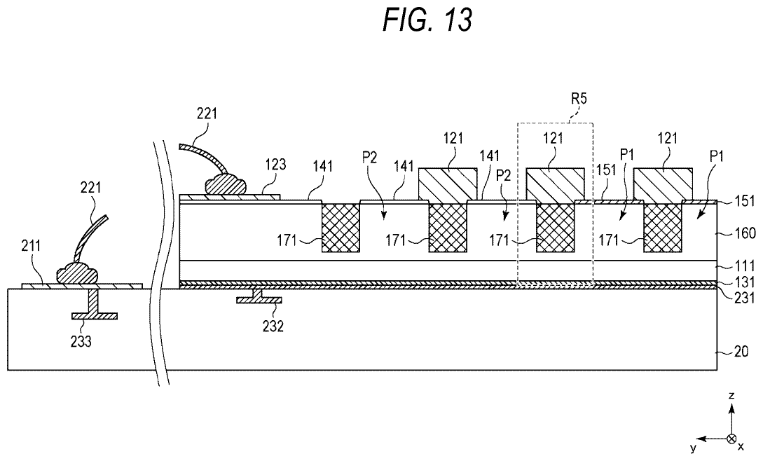

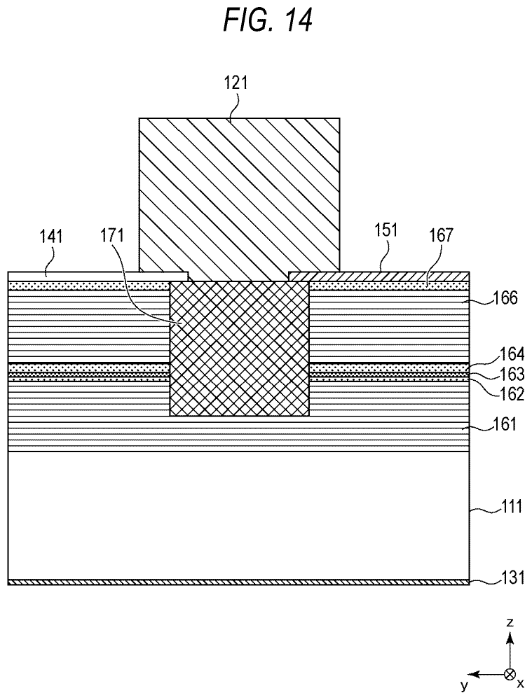

FIG. 13 is a cross-sectional view of the light emitting module according to the present embodiment. Similarly to FIG. 11, FIG. 13 shows a cross section taken along line C-C′ in FIG. 10. FIG. 14 is an enlarged cross-sectional view of the light emitting device 10 according to the present embodiment. FIG. 14 is an enlarged view of a region R5 in FIG. 13.

As shown in FIGS. 13 and 14, the present embodiment is different from the seventh embodiment in that each light emitting portion is not a mesa structure divided by a groove, but a planar structure in which each light emitting portion is divided by an ion-implanted region 171. The ion-implanted region 171 is formed by, for example, an ion implantation process (proton implantation process) of implanting protons (hydrogen cations) into the semiconductor layer 160. The ion-implanted region 171 has a higher resistance than the semiconductor layer 160 which is not ion-implanted. Therefore, the ion-implanted region 171 functions as an insulating region that electrically isolates each light emitting portion, similarly to the groove portion in the mesa structure. Thus, in the present embodiment, an effective light emitting portion P1 and a dummy light emitting portion P2 are formed instead of the effective mesa M1 and the dummy mesa M2. The functions and operations of the effective light emitting portion P1 and the dummy light emitting portion P2 are the same as those of the effective mesa M1 and the dummy mesa M2.

Also in the present embodiment, a light emitting module capable of performing the same operation as in the seventh embodiment and the eighth embodiment is provided. Further, in the present embodiment, the planar structure formed by ion implantation is employed instead of the mesa structure, and the structure and process can be simplified because the groove formation is not necessary. The configuration shown in FIG. 4B of the first embodiment may have the planar structure similar to that of the present embodiment. That is, the structure of FIG. 4B may be modified to the planar structure formed by ion implantation, instead of the mesa structure.

### Tenth Embodiment

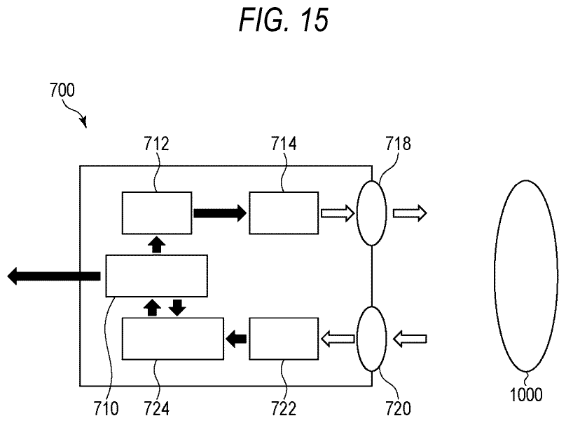

A ranging device according to a tenth embodiment will be described with reference to FIG. 15. FIG. 15 is a block diagram illustrating a schematic configuration of a ranging device according to the present embodiment.

The ranging device 700 according to the present embodiment is a ranging device (LiDAR device) in which the light emitting device 10 or the light emitting module according to any one of the first to ninth embodiments is applied to a light source unit. The ranging device 700 may include a control unit 710, a surface emitting laser array driver 712, a surface emitting laser array 714, a light emitting side optical system 718, a light receiving side optical system 720, an image sensor 722, and a distance data processing unit 724.

The surface emitting laser array 714 is the light emitting device 10 or the light emitting module according to any one of the first to ninth embodiments. The surface emitting laser array driver 712 is a driving unit that receives a driving signal from the control unit 710, generates a driving current for oscillating the surface emitting laser array 714, and outputs the driving current to the surface emitting laser array 714. The surface emitting laser array 714 and the surface emitting laser array driver 712 are not necessarily separate components, and the surface emitting laser array 714 may have the function of the surface emitting laser array driver 712.

The light emitting side optical system 718 is an optical system that emits laser light generated by the surface emitting laser array 714 toward a range to be measured. The light receiving side optical system 720 is an optical system that guides the laser light reflected by the measurement target 1000 to the image sensor 722. In FIG. 15, the light emitting side optical system 718 and the light receiving side optical system 720 are represented by one convex lens-shaped member, but they are not composed of only one convex lens-shaped member, but are composed of a lens group in which a plurality of lenses are combined.

The image sensor 722 is a photoelectric conversion device in which a plurality of pixels including photoelectric conversion units are arranged in a two-dimensional array, and is a light receiving device that outputs an electric signal according to incident light. The image sensor 722 may be, for example, an imaging device such as a CMOS image sensor or a SPAD image sensor. The distance data processing unit 724 has a function as a distance information acquisition unit that generates and outputs information related to the distance to the measurement target 1000 present in the ranging target range based on the signal from the image sensor 722. The distance data processing unit 724 may be electrically connected to the image sensor 722, and may be arranged in the same package as the image sensor 722, or may be arranged in a package different from the image sensor 722.

The control unit 710 is configured by an information processing device or the like including a microcomputer or a logic circuit, and has a function as a central processing device that governs operations in the ranging device 700 such as operation control of each unit and various arithmetic processing.

Next, an operation of the ranging device according to the present embodiment will be described with reference to FIG. 15. First, the control unit 710 outputs a drive signal to the surface emitting laser array driver 712. The surface emitting laser array driver 712 receives the drive signal from the control unit 710 and injects a current of a predetermined current value into the surface emitting laser array 714. Accordingly, the surface emitting laser array 714 oscillates, and laser light is output from the surface emitting laser array 714.

The laser light generated by the surface emitting laser array 714 is emitted toward the range to be measured by the light emitting side optical system 718. Of the laser light irradiated to the measurement target 1000 in the range to be measured, the laser light reflected by the measurement target 1000 and incident on the light receiving side optical system 720 is guided to the image sensor 722 by the light receiving side optical system 720.

Each pixel of the image sensor 722 generates an electrical signal pulse according to the timing of incidence of the laser light. The electric signal pulse generated by the image sensor 722 is input to the distance data processing unit 724.

The distance data processing unit 724 generates information on the distance to the measurement target 1000 along the light propagation direction based on the reception timing of the electric signal pulse output from the image sensor 722. For example, the information on the distance to the measurement target 1000 is generated based on the time difference between the timing at which the light is emitted from the surface emitting laser array 714 and the timing at which the light is received by the image sensor 722. By calculating distance information based on electric signal pulses output from each pixel of the image sensor 722, it is possible to acquire three-dimensional information of the measurement target 1000.

The ranging device 700 of the present embodiment is applicable to, for example, a control device for performing control so as not to collide with another vehicle, a control device for performing control so as to automatically drive following another vehicle, and the like in the field of automobiles. The ranging device 700 of the present embodiment is applicable not only to an automobile but also to another mobile object (moving device) such as a ship, an aircraft, or an industrial robot, a mobile object detection system, or the like. The ranging device 700 according to the present embodiment can be widely applied to equipment that uses information of an object recognized three-dimensionally, including distance information. These mobile object may be configured to include the ranging device of the present embodiment and a control unit that controls a mobile object based on the information on the distance acquired by the ranging device.

The three-dimensional information including the depth that can be acquired by the ranging device 700 of the present embodiment can also be used in an image capturing device, an image processing device, a display device, or the like. For example, by using the three-dimensional information acquired by the ranging device 700 of the present embodiment, it is possible to display a virtual object on an image of the real world without a sense of discomfort. In addition, by storing the three-dimensional information together with the image information, it is also possible to correct the blur or the like of the photographed image after photographing.

### Eleventh Embodiment

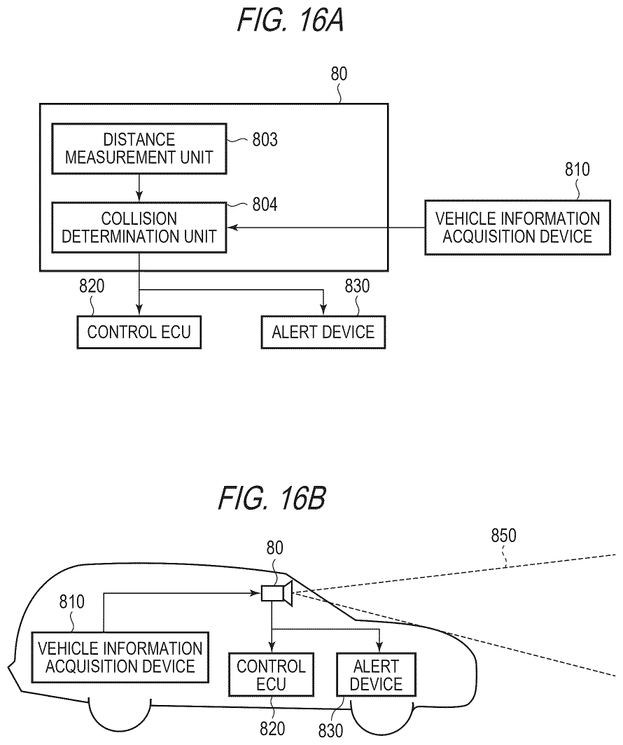

A mobile object according to the eleventh embodiment will be described with reference to FIGS. 16A and 16B. FIGS. 16A and 16B are block diagrams illustrating a configuration example of a mobile object according to the present embodiment.

FIG. 16A shows a configuration example of equipment mounted on a vehicle as an in-vehicle camera. The equipment 80 includes a distance measurement unit 803 that measures a distance to a distance measurement target, and a collision determination unit 804 that determines whether or not there is a possibility of collision based on the distance measured by the distance measurement unit 803. The distance measurement unit 803 may be configured by, for example, the ranging device 700 described in the tenth embodiment. Here, the distance measurement unit 803 is an example of a distance information acquisition unit that acquires distance information to the distance measurement target. That is, the distance information is information related to the distance to the distance measurement target or the like.

The equipment 80 is connected to the vehicle information acquisition device 810, and can obtain vehicle information such as a vehicle speed, a yaw rate, and a steering angle. Further, the equipment 80 is connected to a control ECU 820 which is a control device that outputs a control signal for generating a braking force to the vehicle based on the determination result of the collision determination unit 804. The equipment 80 is also connected to an alert device 830 that issues an alert to the driver based on the determination result of the collision determination unit 804. For example, when the collision possibility is high as the determination result of the collision determination unit 804, the control ECU 820 performs vehicle control to avoid collision or reduce damage by braking, returning an accelerator, suppressing engine output, or the like. The alert device 830 alerts the user by sounding an alarm such as a sound, displaying alert information on a screen of a car navigation system or the like, or giving vibration to a seat belt or a steering wheel. These devices of the equipment 80 functions as a mobile object control unit that controls the operation of controlling the vehicle as described above.

In the present embodiment, the distance to the surroundings of the vehicle, for example, the front or the rear is measured by the equipment 80. FIG. 16B shows equipment in a case where ranging in front of the vehicle (ranging range 850) is performed. The vehicle information acquisition device 810 as the ranging control unit sends an instruction to the equipment 80 or the distance measurement unit 803 to perform the ranging operation. With such a configuration, the accuracy of ranging can be further improved.

Although the example of control for avoiding a collision to another vehicle has been described above, the embodiment is applicable to automatic driving control for following another vehicle, automatic driving control for not going out of a traffic lane, or the like. Furthermore, the equipment is not limited to a vehicle such as an automobile and can be applied to a mobile object (movable apparatus) such as a ship, an airplane, a satellite, an industrial robot and a consumer use robot, or the like, for example. In addition, the equipment can be widely applied to equipment which utilizes object recognition or biometric authentication, such as an intelligent transportation system (ITS), a surveillance system, or the like without being limited to movable bodies.

### Modified Embodiments

The present disclosure is not limited to the above embodiments, and various modifications are possible. For example, an example in which some of the configurations of any one of the embodiments are added to other embodiments or an example in which some of the configurations of any one of the embodiments are replaced with some of the configurations of other embodiments are also embodiments of the present disclosure.

The disclosure of this specification includes a complementary set of the concepts described in this specification. That is, for example, if a description of “A is B” (A=B) is provided in this specification, this specification is intended to disclose or suggest that “A is not B” even if a description of “A is not B” (A≠B) is omitted. This is because it is assumed that “A is not B” is considered when “A is B” is described.

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

It should be noted that the above-described embodiments are merely specific examples for carrying out the present disclosure, and the technical scope of the present disclosure should not be interpreted in a limited manner by these embodiments. That is, the present disclosure can be implemented in various forms without departing from the technical idea or the main features thereof.

According to the present disclosure, a light emitting device capable of further improving uniformity of characteristics is provided.

While the present disclosure has been described with reference to exemplary embodiments, it is to be understood that the embodiments are not limited to the disclosed exemplary embodiments. The scope of the following claims is to be accorded the broadest interpretation so as to encompass all such modifications and equivalent structures and functions.

This application claims the benefit of Japanese Patent Application No. 2024-107551, filed Jul. 3, 2024, which is hereby incorporated by reference herein in its entirety.

What is claimed is:

1. A light emitting device comprising:
a substrate;
a first light emitting element arranged on the substrate;
a second light emitting element arranged on the substrate; and
a wiring layer arranged over the first light emitting element and the second light emitting element,
wherein each of the first light emitting element and the second light emitting element is a vertical cavity surface emitting laser (VCSEL) element,
wherein the first light emitting element is configured to emit light by being supplied with electric power from the wiring layer, and
wherein the second light emitting element is configured such that electric power for causing the second light emitting element to emit light is not supplied from the wiring layer to the second light emitting element.

2. The light emitting device according to claim 1, wherein the wiring layer is not electrically connected to the second light emitting element.

3. The light emitting device according to claim 1 further comprising a first insulating film that insulates the wiring layer and the second light emitting element from each other.

4. The light emitting device according to claim 1,
wherein the wiring layer includes a first wiring arranged over a region in which the first light emitting device is arranged and a second wiring arranged over a region in which the second light emitting device is arranged, and
wherein the first wiring and the second wiring are not electrically connected to each other.

5. The light emitting device according to claim 4, wherein a ground potential is supplied to the second wiring.

6. The light emitting device according to claim 4, wherein the second wiring is in a floating state.

7. The light emitting device according to claim 4 further comprising a second insulating film that insulates a part of the first wiring and a part of the first light emitting element from each other.

8. The light emitting device according to claim 1, wherein in a plan view with respect to the substrate, the second light emitting element is arranged between the first light emitting element and an end of the substrate.

9. The light emitting device according to claim 1, wherein in a plan view with respect to the substrate, a shape of an end of a part of the wiring layer arranged over the first light emitting element and a shape of an end of a part of the wiring layer arranged over the second light emitting element are different from each other.

10. The light emitting device according to claim 1, wherein in a plan view with respect to the substrate, at least a part of the wiring layer has a lattice shape.

11. The light emitting device according to claim 1 further including a pad arranged to surround the first light emitting device and the second light emitting device in a plan view with respect to the substrate.

12. The light emitting device according to claim 1 further comprising a plurality of the first light emitting elements,
wherein the wiring layer is configured to supply different potentials to the plurality of first light emitting elements.

13. The light emitting device according to claim 1 further comprising a control circuit configured to supply electric power to the wiring layer.

14. The light emitting device according to claim 1 further comprising a plurality of the second light emitting elements,
wherein patterns of the wiring layer over the plurality of second light emitting devices are different from each other.

15. The light emitting device according to claim 1, wherein each of the first light emitting device and the second light emitting device includes a plurality of mesas.

16. The light emitting device according to claim 15, wherein a semiconductor layer forming a mesa included in the first light emitting element and a semiconductor layer forming a mesa included in the second light emitting element have the same structure.

17. The light emitting device according to claim 15, wherein a part of the wiring layer is arranged so as to cover a groove between the plurality of mesas.

18. The light emitting device according to claim 17 further comprising a transparent conductive film electrically connecting the wiring layer and an upper surface of a mesa included in the first light emitting element.

19. The light emitting device according to claim 17,
wherein in a plan view with respect to the substrate, the mesa has a rectangular shape, and
wherein in the plan view with respect to the substrate, the wiring layer overlaps three sides of the mesa and the wiring layer does not overlap one side of the mesa.

20. The light emitting device according to claim 3,
wherein a semiconductor layer forming a mesa included in the first light emitting element and a semiconductor layer forming a mesa included in the second light emitting element have the same structure,
wherein the first insulating film is arranged on an entire surface of a groove between the mesa of the first light emitting element and the mesa of the second light emitting element,
wherein a transparent conductive film is arranged on a side surface of the mesa of the first light emitting element and an upper surface of the mesa of the first light emitting element,
wherein the transparent conductive film is neither arranged on a side surface of the mesa of the second light emitting element nor an upper surface of the mesa of the second light emitting element, and
wherein the wiring layer and the transparent conductive film are electrically connected to each other.

21. The light emitting device according to claim 1,
wherein each of the first light emitting device and the second light emitting device includes a semiconductor layer in which an insulating region is formed, and
wherein a part of the wiring layer is arranged so as to cover the insulating region.

22. A method of manufacturing the light emitting device according to claim 21, wherein the insulating region is formed by selectively implanting ions into a part of the semiconductor layer.

23. A method of manufacturing the light emitting device according to claim 1 comprising:
forming a resist for patterning the wiring layer, on the substrate; and
forming the wiring layer by plating.

24. A ranging device comprising:
the light emitting device according to claim 1;
a light receiving device configured to receive light emitted from the light emitting device and reflected by a measurement target; and
a distance information acquisition unit configured to acquire information on a distance to the measurement target based on a time difference between a timing at which the light is emitted from the light emitting device and a timing at which the light receiving device receives the light.

25. A mobile object comprising:
the ranging device according to claim 24; and
a control unit configured to control the mobile object based on the information on the distance acquired by the ranging device.
